(19) United States
(12) Patent Application Publication
(10) Pub. No.: US 2022/0093557 A1
(43) Pub. Date: Mar. 24, 2022

(54) CHIP-TRANSFERRING SYSTEM AND CHIP-TRANSFERRING METHOD

(71) Applicant: Skiileux Electricity Inc., Taoyuan City (TW)

(72) Inventor: Chien-Shou Liao, Taoyuan City (TW)

(73) Assignee: Skiileux Electricity Inc., Taoyuan City (TW)

(21) Appl. No.: 17/474,068

(22) Filed: Sep. 14, 2021

(30) Foreign Application Priority Data
Sep. 18, 2020 (TW) 109132276

(51) Int. Cl. H01L 23/00; H01L 21/48; H01L 21/67; H01L 21/683

(52) U.S. Cl. CPC H01L 24/81; H01L 24/16; H01L 21/4853; H01L 21/67144; H01L 21/6835; H01L 2224/81815; H01L 2221/68363; H01L 2221/68381; H01L 2224/16227; H01L 2224/81005; H01L 2224/81238; H01L 2221/68354

(57) ABSTRACT

A chip-transferring system and a chip-transferring method are provided. The chip-transferring method includes: providing a chip carrying structure carrying an electronic chip; providing a circuit substrate, wherein a soldering material is configured between the electronic chip and the circuit substrate; providing a pin structure, wherein the electronic chip is transferred from the chip carrying structure to the circuit substrate through thrust of the pin structure; approaching a conductive coil structure of an eddy current generating module toward the soldering material , so that the soldering material is heated and cured indirectly through an eddy current generated by the conductive coil structure.

### CROSS-REFERENCE TO RELATED APPLICATION

This application claims the priority benefit of Taiwanese application no. 109132276, filed on Sep. 18, 2020. The entirety of the above-mentioned patent application is hereby incorporated by reference herein and made a part of this specification.

### BACKGROUND

### Technical Field

The disclosure relates to a transferring system and a transferring method, and particularly relates to a chip-transferring system and a chip-transferring method.

### Description of Related Art

A light-emitting diode chip may be transferred from one carrier to another through a thrust action of a pin, and then the light-emitting diode chip may be mounted on a circuit board through an external heating method (for example, by using a reflow oven). However, the existing transferring method of light-emitting diode chip still has room for improvement.

### SUMMARY

The technical problem to be solved by the disclosure is to provide a chip-transferring system and a chip-transferring method for mending deficiencies.

In order to solve the above technical problems, one of the technical solutions adopted by the disclosure is to provide a chip-transferring system, which includes: a pin structure, a chip carrying structure, a substrate carrying module, and an eddy current generating module. The chip carrying structure is used for carrying a chip group including a plurality of electronic chips. The substrate carrying module is used for carrying a circuit substrate, and the circuit substrate has a plurality of conductive pads. The eddy current generating module includes a conductive coil structure and a controller electrically connected to the conductive coil structure, wherein an indirect heating of a soldering material between the electronic chip and the circuit substrate is passed through an eddy current generated by the conductive coil structure and then cured.

In order to solve the above technical problems, another technical solution adopted by the disclosure is to provide a chip-transferring method, which includes: providing a chip carrying structure, wherein the chip carrying structure carries an electronic chip; providing a circuit substrate, wherein a soldering material is a between the electronic chip and the circuit substrate; providing a pin structure, wherein the electronic chip is transferred from the chip carrying structure to the circuit substrate through thrust of the pin structure; approaching a conductive coil structure of an eddy current generating module toward the soldering material , so that an indirect heating of a soldering material is passed through an eddy current generated by the conductive coil structure and then cured.

One of beneficial effects of the disclosure is that the chip-transferring system provided by the disclosure may adopt technical solutions of “a chip thrust module includes a pin structure adjacent to the chip carrying structure” and “the eddy current generating module includes a conductive coil structure” and “the soldering materials between the electronic chips and the circuit substrate is indirectly heated and cured through the eddy current generated by the conductive coil structure”, a corresponding micro heater or the pin structure may be heated by the eddy current generated by the conductive coil structure, and the two soldering materials arranged between the electronic chips and the circuit substrate may be cured through heating of the corresponding micro heater or the pin structure.

One of beneficial effects of the disclosure is that the chip-transferring method provided by the disclosure may adopt technical solutions of “providing the pin structure to transfer the electronic chips from the chip carrying structure to the circuit substrate through thrust of the pin structure” and “approaching the conductive coil structure of the eddy current generating module toward the soldering materials, so that the soldering materials are heated and cured indirectly through the eddy current generated by the conductive coil structure”, the micro heater or the pin structure may be heated by the eddy current generated by the conductive coil structure, and the two soldering materials arranged between the electronic chips and the circuit substrate may be cured through heating of the micro heater or the pin structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a chip-transferring system according to a first embodiment of the disclosure.

FIG. 2 is a schematic diagram of transferring electronic chips from a chip carrying structure to a circuit substrate by the chip-transferring system according to the first embodiment of the disclosure.

FIG. 3 is a schematic diagram of the electronic chips completely away from the chip carrying structure and arranged on the circuit substrate according to the first embodiment of the disclosure.

FIG. 4 is a schematic diagram of transferring the electronic chips from the chip carrying structure to the circuit substrate by the chip-transferring system according to a second embodiment of the disclosure.

FIG. 5 is a schematic diagram of transferring the electronic chips from the chip carrying structure to the circuit substrate by the chip-transferring system according to a third embodiment of the disclosure.

FIG. 6 is a schematic diagram of transferring the electronic chips from the chip carrying structure to the circuit substrate by the chip-transferring system according to a fourth embodiment of the disclosure.

FIG. 7 is a schematic diagram of transferring the electronic chips from the chip carrying structure to the circuit substrate by the chip-transferring system according to a fifth embodiment of the disclosure.

FIG. 8 is a schematic diagram of transferring the electronic chips from the chip carrying structure to the circuit substrate by the chip-transferring system according to a sixth embodiment of the disclosure.

FIG. 9 is a schematic diagram of a chip-transferring system according to a seventh embodiment of the disclosure.

FIG. 10 is a schematic diagram of transferring the electronic chips from the chip carrying structure to the circuit substrate by the chip-transferring system according to the seventh embodiment of the disclosure.

FIG. 11 is a schematic diagram of transferring the electronic chips from the chip carrying structure to the circuit substrate by the chip-transferring system according to an eighth embodiment of the disclosure.

FIG. 12 is a schematic diagram of transferring the electronic chips from the chip carrying structure to the circuit substrate by the chip-transferring system according to a ninth embodiment of the disclosure.

FIG. 13 is a schematic diagram of transferring the electronic chips from the chip carrying structure to the circuit substrate by the chip-transferring system according to a tenth embodiment of the disclosure.

FIG. 14 is a schematic diagram of transferring the electronic chips from the chip carrying structure to the circuit substrate by the chip-transferring system according to an eleventh embodiment of the disclosure.

FIG. 15 is a schematic diagram of transferring the electronic chips from the chip carrying structure to the circuit substrate by the chip-transferring system according to a twelfth embodiment of the disclosure.

FIG. 16 is a schematic diagram of transferring the electronic chips from the chip carrying structure to the circuit substrate by the chip-transferring system according to a thirteenth embodiment of the disclosure.

### DESCRIPTION OF THE EMBODIMENTS

A following specific embodiment is provided below to describe implementation of the “chip-transferring system and chip-transferring method” disclosed in the disclosure. Those skilled in the art may understand advantages and effects of the disclosure from the content disclosed in this specification. The disclosure may be implemented by or applied to other different specific embodiments, and various details in this specification may also be modified and changed based on different viewpoints and applications without departing from the concept of the disclosure. In addition, the drawings of the disclosure are merely schematic illustrations, and are not drawn according to actual dimensions, which is stated in advance. The following embodiments will further describe the related technical content of the disclosure in detail, but the disclosed content is not intended to limit a protection scope of the disclosure. In addition, the term “or” used in this specification probably include any one or a combination of more of the associated listed items depending on an actual situation.

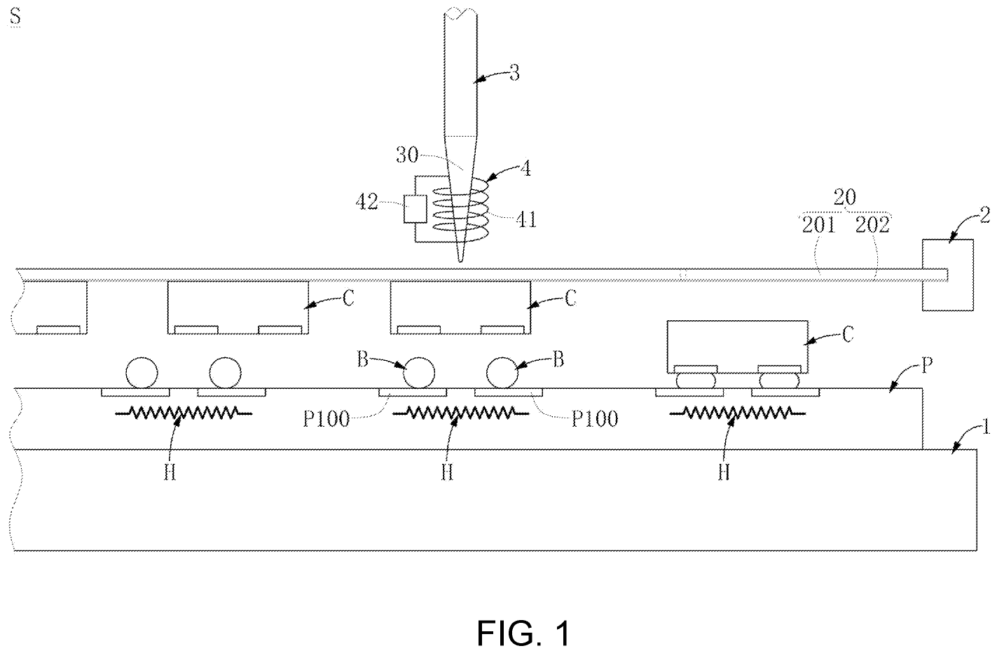

Referring to FIG. 1 to FIG. 15, the disclosure provides a chip-transferring system S, which includes: a substrate carrying module 1, a chip carrying module 2, a chip thrust module 3, and an eddy current generating module 4. The substrate carrying module 1 is used to carry a circuit substrate P. The chip carrying module 2 includes a chip carrying structure 20 adjacent to the substrate carrying module 1 for carrying a chip group including a plurality of electronic chips C. The chip thrust module 3 includes a pin structure 30 adjacent to the chip carrying structure 20. The eddy current generating module 4 includes a conductive coil structure 41. A plurality of micro heaters H are arranged on at least one of the circuit substrate P, the chip group including the plurality of electronic chips C, and the chip carrying structure 20, or the micro heaters H are not used.

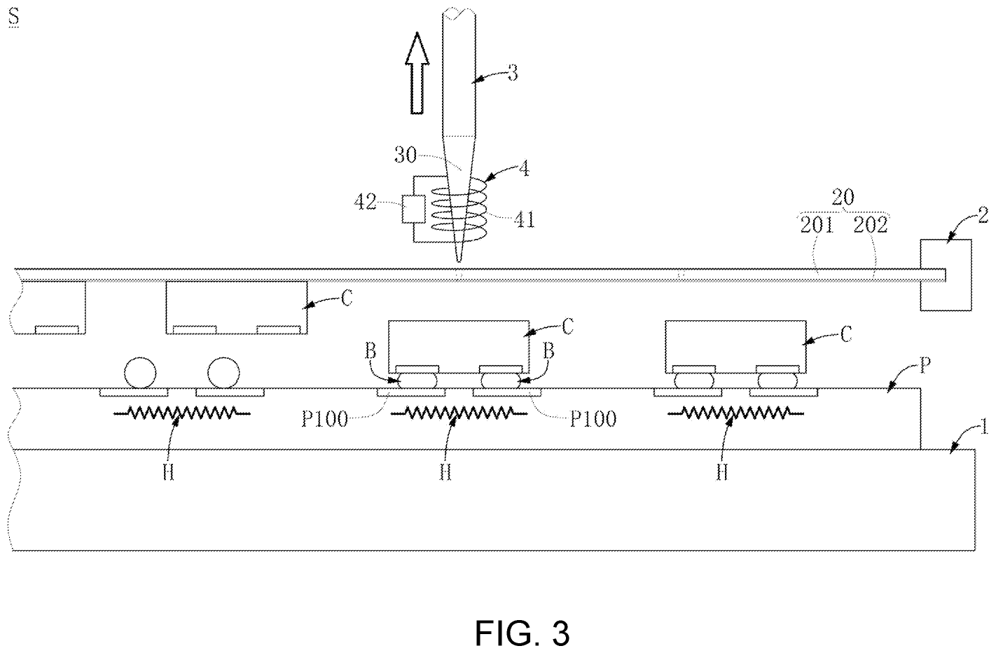

Referring to FIG. 1 to FIG. 15, the disclosure provides a chip-transferring method, which includes following steps. First, the electronic chip C is transferred from the chip carrying structure 20 to the circuit substrate P through thrust of the pin structure 30, two soldering materials B are arranged between the electronic chip C and the circuit substrate P, and a micro heater H is provided on at least one of the circuit substrate P, the electronic chip C, and the chip carrying structure 20 or the micro heater H is not used. Then, the conductive coil structure 41 of the eddy current generating module 4 and the micro heater H are approached to each other. Then, an eddy current 4100 generated by the conductive coil structure 41 is used to heat the micro heater H. Then, as shown in FIG. 3, through the heat generated by the micro heater H, the two soldering materials B are heated and cured, i.e., by approaching the conductive coil structure 41 of the eddy current generating module 4 toward the soldering materials B, the soldering materials B may be indirectly heated and cured through the eddy current generated by the conductive coil structure 41.

### First Embodiment

Referring to FIG. 1 to FIG. 3, the first embodiment of the disclosure provides a chip-transferring system S, which includes: a substrate carrying module 1, a chip carrying module 2, a chip thrust module 3 and an eddy current generating module 4.

Further, as shown in FIG. 1, the substrate carrying module 1 may be used to carry the circuit substrate P, and the circuit substrate P has a plurality of conductive pads P100. For example, the substrate carrying module 1 may be a carrying platform that may move along a horizontal plane, and the plurality of soldering materials B (such as solder balls, solder pastes, or any conductive materials) may be respectively pre-placed on the plurality of conductive pads P100. However, the above-mentioned example is only one of the feasible embodiments and is not intended to limit the disclosure.

Further, as shown in FIG. 1, the chip carrying module 2 includes a chip carrying structure 20 disposed above the substrate carrying module 1 for carrying a chip group including a plurality of electronic chips C. For example, the chip carrying structure 20 may be a blue film for carrying a plurality of electronic chips C. The chip carrying structure 20 includes an elastic film 201 facing away from the circuit substrate P and an adhesive layer 202 facing the circuit substrate P, and the adhesive layer 202 is disposed on the elastic film 201. In this way, through the adhesiveness provided by the adhesive layer 202 of the chip carrier structure 20, the plurality of electronic chips C may be disposed on the adhesive layer 202. However, the above-mentioned example is only one of the feasible embodiments and is not intended to limit the disclosure.

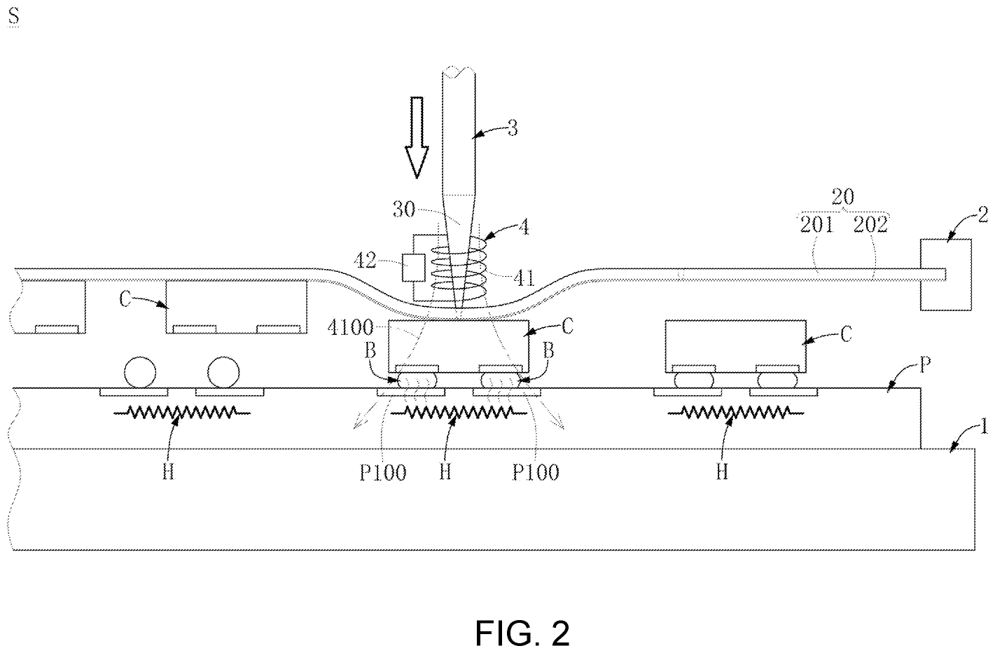

Further, as shown in FIG. 1, the chip thrust module 3 includes the pin structure 30 disposed above the chip carrying structure 20, and the eddy current generating module 4 includes the conductive coil structure 41 and a controller 42 electrically connected to the conductive coil structure 41. For example, the conductive coil structure 41 may be made of any conductive material. The pin structure 30 is surrounded by the conductive coil structure 41. A position of the conductive coil structure 41 corresponds to one of the plurality of micro heaters H, and the conductive coil structure 41 and the pin structure 30 may be moved synchronously (as shown in FIG. 1 to FIG. 3). In addition, in the disclosure, a current may be transmitted to the conductive coil structure 41 through control of the controller 42 (for example, a control switch). When the conductive coil structure 41 receives the current, the conductive coil structure 41 may generate the eddy current 4100 (as shown in FIG. 2). However, the above-mentioned example is only one of the feasible embodiments and is not intended to limit the disclosure.

Furthermore, the plurality of micro heaters H may be arranged on at least one of the circuit substrate P, the chip group including the plurality of electronic chips C, and the chip carrying structure 20, and the plurality of micro heaters H may respectively correspond to a plurality of electronic chips C. Moreover, the plurality of micro heaters H are independent and electrically insulated from each other, and the micro heaters H are electrically insulated from the circuit substrate P, the electronic chips C, and the chip carrying structure 20. For example, as shown in FIG. 1, the plurality of micro heaters H provided by the first embodiment of the disclosure are all arranged in the circuit substrate P, and the plurality of micro heaters H will not be electrically connected with other circuit layouts or electronic components arranged on the circuit substrate P. In addition, each micro heater H may be a conductive substance, and the conductive substance may be made of any conductive material, such as a metal material or a semiconductor material. However, the above-mentioned example is only one of the feasible embodiments and is not intended to limit the disclosure.

In this way, as shown in FIG. 2, when the electronic chips C are transferred from the chip carrying structure 20 to the circuit substrate P through thrust of the pin structure 30, the conductive coil structure 41 of the eddy current generating module 4 may approach the corresponding micro heater H, so that the corresponding micro heater H may be heated through the eddy current 4100 generated by the conductive coil structure 41. In addition, when the electronic chips C are transferred from the chip carrying structure 20 to the circuit substrate P through the thrust of the pin structure 30, the two soldering materials B arranged between the electronic chips C and the circuit substrate P may be heated and cured by the corresponding micro heater H, so that one of the soldering materials B may be fixed between one of chip pads of the electronic chips C and one of the conductive pads P100 of the circuit board P, and the other soldering material B may be fixed between another chip pad of the electronic chips C and another conductive pad P100 of the circuit substrate P. Furthermore, as shown in FIG. 2, in the first embodiment (a plurality of micro heaters H are arranged in the circuit substrate P), when the conductive coil structure 41 is approached to the corresponding micro heater H, the heat generated by the corresponding micro heater H may be transferred to the corresponding two soldering materials B through the circuit substrate P to heat the corresponding two soldering materials B, so that in the embodiment, the indirect heating is to bring the conductive coil structure 41 of the eddy current generating module 4 close to the micro heater H to heat the micro heater H through the eddy current 4100 generated by the conductive coil structure 41, and then the soldering material B is heated and cured by the heat generated by the micro heater H.

### Second Embodiment

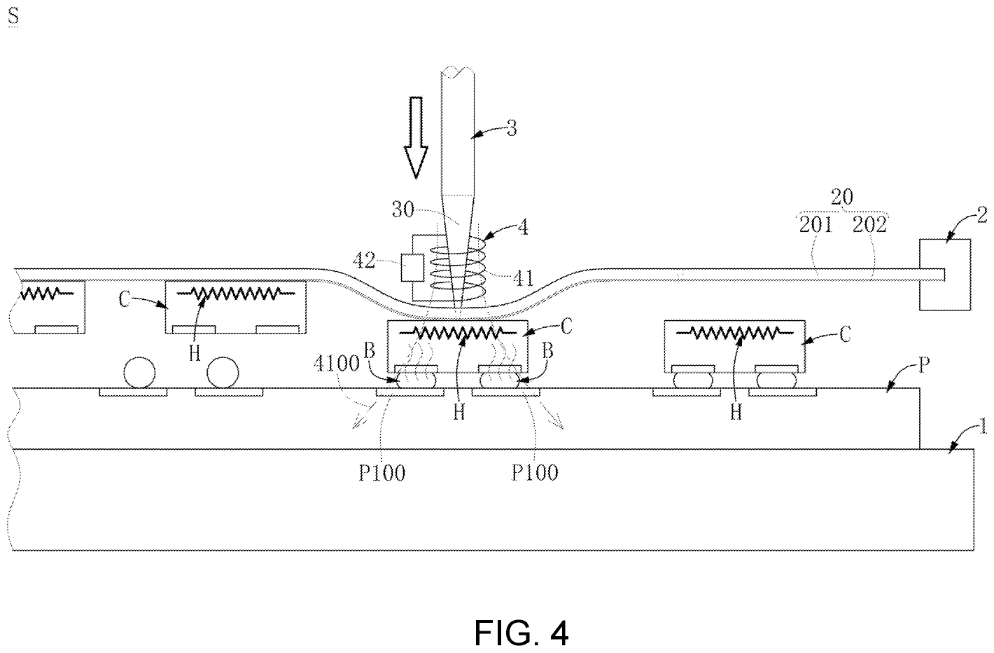

Referring to FIG. 4, the second embodiment of the disclosure provides a chip-transferring system S, which includes a substrate carrying module 1, a chip carrying module 2, a chip thrust module 3 and an eddy current generating module 4. From the comparison between FIG. 4 and FIG. 2, it is learned that the biggest difference between the second embodiment and the first embodiment of the disclosure is that: in the second embodiment, the plurality of micro heaters H are arranged in the plurality of electronic chips C, respectively.

In this way, as shown in FIG. 4, when the electronic chips C are transferred from the chip carrying structure 20 to the circuit substrate P through thrust of the pin structure 30, the conductive coil structure 41 of the eddy current generating module 4 may approach the corresponding micro heater H, so that the corresponding micro heater H may be heated through the eddy current 4100 generated by the conductive coil structure 41. In addition, when the electronic chips C are transferred from the chip carrying structure 20 to the circuit substrate P through the thrust of the pin structure 30, the two soldering materials B arranged between the electronic chips C and the circuit substrate P may be heated and cured by the corresponding micro heater H. Furthermore, as shown in FIG. 4, in the second embodiment (a plurality of micro heaters H are respectively arranged in the electronic chips C), when the conductive coil structure 41 is approached to the corresponding micro heater H, the heat generated by the corresponding micro heater H may be transferred to the corresponding two soldering materials B through the corresponding electronic chips C to heat the corresponding two soldering materials B. It should be noted that in the embodiment, the mechanism of indirect heating is similar to that of the first embodiment, which is not repeated.

### Third Embodiment

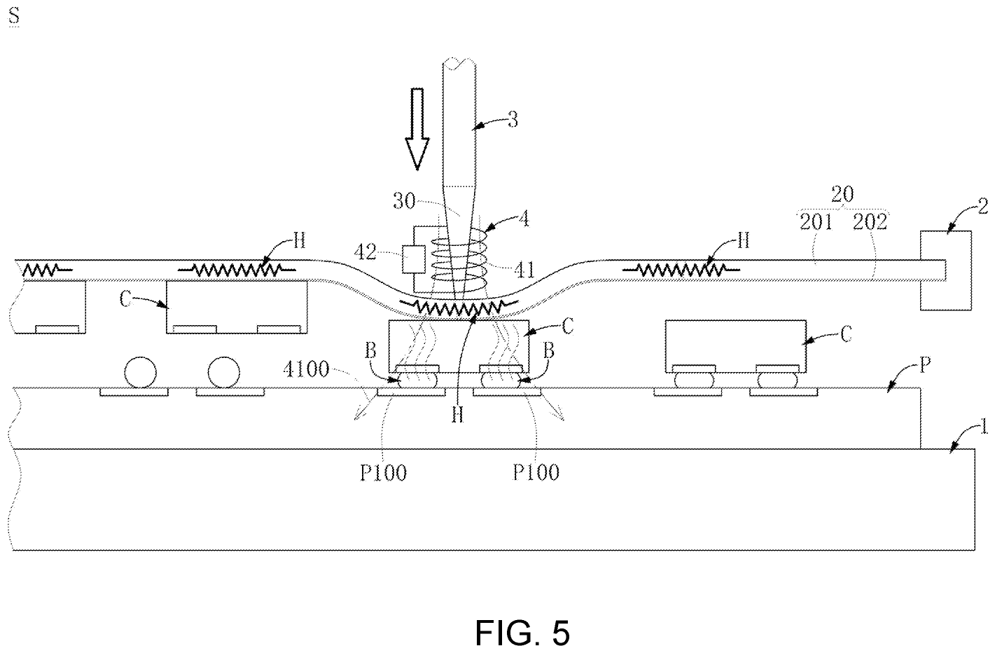

Referring to FIG. 5, the third embodiment of the disclosure provides a chip-transferring system S, which includes: a substrate carrying module 1, a chip carrying module 2, a chip thrust module 3, and an eddy current generating module 4.

From the comparison between FIG. 5 and FIG. 2, it is learned that the biggest difference between the third embodiment and the first embodiment of the disclosure is that: in the third embodiment, the plurality of micro heaters H are arranged in the chip carrying structure 20.

In this way, as shown in FIG. 5, when the electronic chips C are transferred from the chip carrying structure 20 to the circuit substrate P through thrust of the pin structure 30, the conductive coil structure 41 of the eddy current generating module 4 may approach the corresponding micro heater H, so that the corresponding micro heater H may be heated through the eddy current 4100 generated by the conductive coil structure 41. In addition, when the electronic chips C are transferred from the chip carrying structure 20 to the circuit substrate P through the thrust of the pin structure 30, the two soldering materials B arranged between the electronic chips C and the circuit substrate P may be heated and cured by the corresponding micro heater H. Furthermore, as shown in FIG. 5, in the third embodiment (a plurality of micro heaters H are arranged in the chip carrying structure 20), when the conductive coil structure 41 is approached to the corresponding micro heater H, the heat generated by the corresponding micro heater H may be transferred to the corresponding two soldering materials B sequentially through the chip carrying structure 20 and the corresponding electronic chips C to heat the corresponding two soldering materials B. It should be noted that in the embodiment, the mechanism of indirect heating is similar to that of the first embodiment, which is not repeated.

### Fourth Embodiment

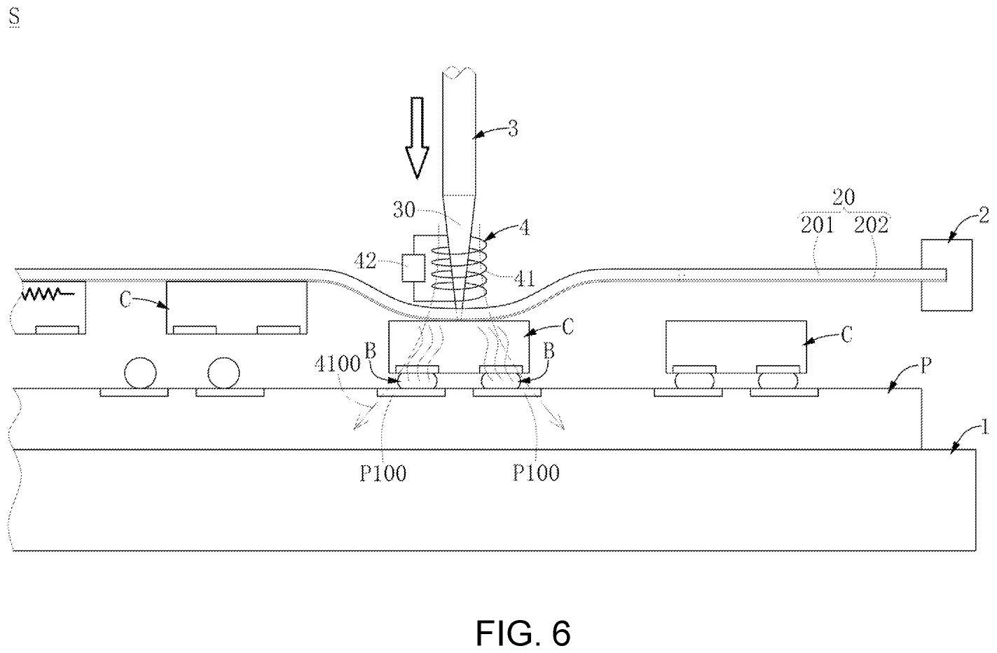

Referring to FIG. 6, the fourth embodiment of the disclosure provides a chip-transferring system S, which includes: a substrate carrying module 1, a chip carrying module 2, a chip thrust module 3, and an eddy current generating module 4. From the comparison between FIG. 6 and FIG. 2, it is learned that the biggest difference between the fourth embodiment and the first embodiment of the disclosure is that: in the fourth embodiment, it is unnecessary to use the micro heaters H.

In this way, as shown in FIG. 6, when the electronic chips C are transferred from the chip carrying structure 20 to the circuit substrate P through thrust of the pin structure 30, the conductive coil structure 41 of the eddy current generating module 4 may approach the pin structure 30, so that the pin structure 30 may be heated through the eddy current 4100 generated by the conductive coil structure 41. In addition, when the electronic chips C are transferred from the chip carrying structure 20 to the circuit substrate P through the thrust of the pin structure 30, the two soldering materials B arranged between the electronic chips C and the circuit substrate P may be heated and cured by the pin structure 30. Furthermore, as shown in FIG. 6, when the conductive coil structure 41 is approached to the pin structure 30, the heat generated by the corresponding micro heater H may be transferred to the corresponding two soldering materials B sequentially through the chip carrying structure 20 and the corresponding electronic chips C to heat the corresponding two soldering materials B. Therefore, in the embodiment, the indirect heating is to bring the conductive coil structure 41 of the eddy current generating module 4 close to the pin structure 30, so as to heat the pin structure 30 through the eddy current 4100 generated by the conductive coil structure 41, and then the soldering materials B are heated and cured by the heat generated by the pin structure 30.

### Fifth Embodiment

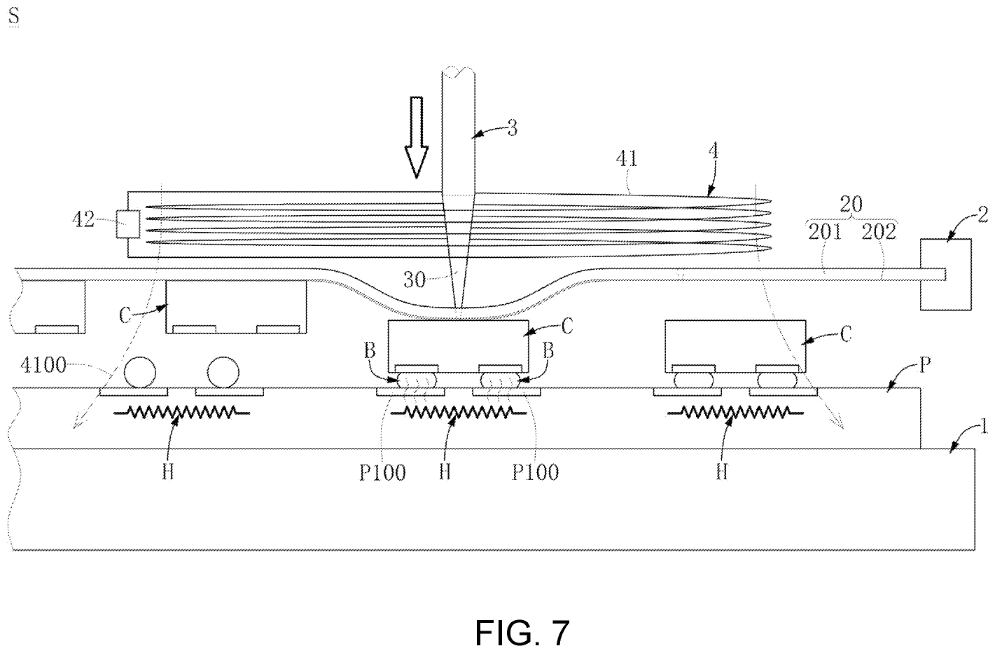

Referring to FIG. 7, the fifth embodiment of the disclosure provides a chip-transferring system S, which includes: a substrate carrying module 1, a chip carrying module 2, a chip thrust module 3, and an eddy current generating module 4. From the comparison between FIG. 7 and FIG. 2, it is learned that the biggest difference between the fifth embodiment and the first embodiment of the disclosure is that: in the fifth embodiment, the conductive coil structure 41 is arranged at a position corresponding to one or more micro heaters H, so as to increase the eddy current 4100 provided by the conductive coil structure 41. It should be noted that in the embodiment, the mechanism of indirect heating is similar to that of the first embodiment, which is not repeated.

### Sixth Embodiment

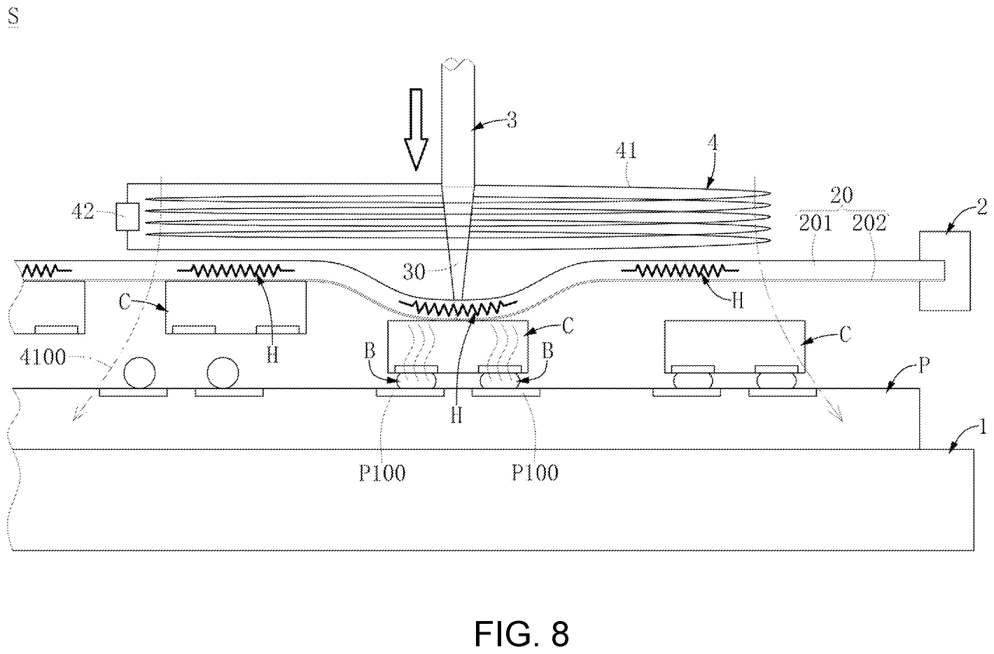

Referring to FIG. 8, the sixth embodiment of the disclosure provides a chip-transferring system S, which includes: a substrate carrying module 1, a chip carrying module 2, a chip thrust module 3, and an eddy current generating module 4. From the comparison between FIG. 8 and FIG. 5, it is learned that the biggest difference between the sixth embodiment and the third embodiment of the disclosure is that: in the sixth embodiment, the conductive coil structure 41 is arranged at a position corresponding to one or more micro heaters H, so as to increase the eddy current 4100 provided by the conductive coil structure 41. It should be noted that in the embodiment, the mechanism of indirect heating is similar to that of the first embodiment, which is not repeated.

### Seventh Embodiment

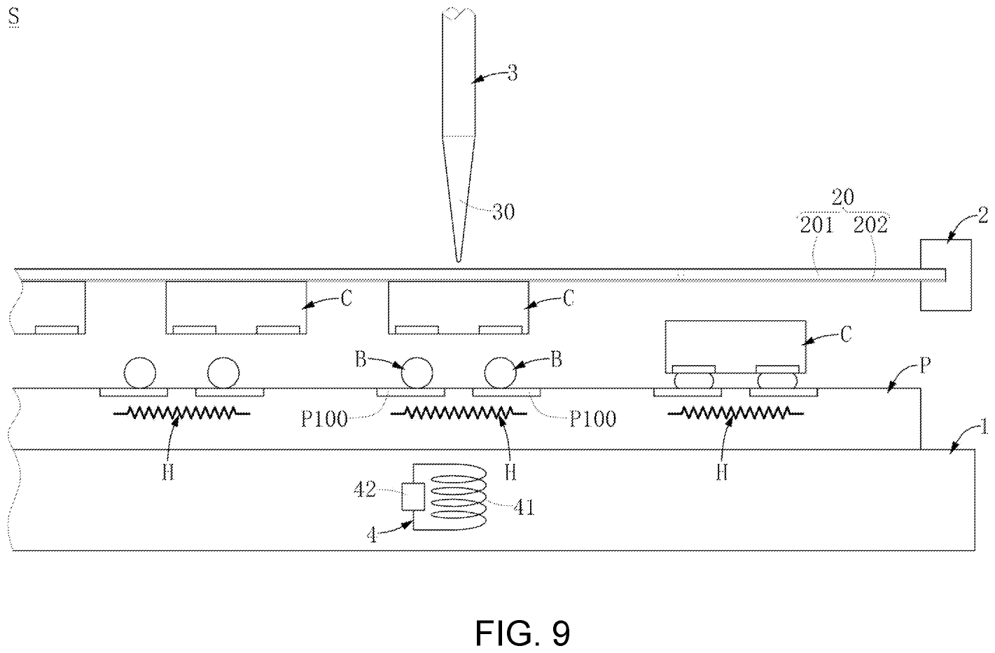

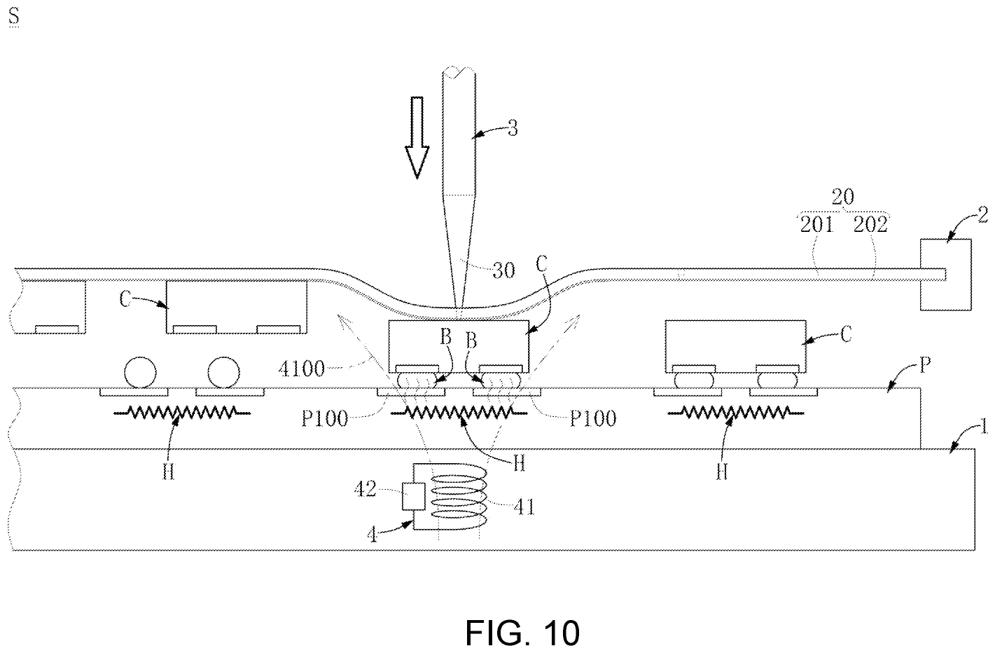

Referring to FIG. 9 and FIG. 10, the seventh embodiment of the disclosure provides a chip-transferring system S, which includes: a substrate carrying module 1, a chip carrying module 2, a chip thrust module 3, and an eddy current generating module 4. From the comparison between FIG. 9 and FIG. 1 and the comparison between FIG. 10 and FIG. 2, it is learned that the biggest difference between the seventh embodiment and the first embodiment of the disclosure is that: in the seventh embodiment, the circuit substrate P is disposed between the pin structure 30 and the conductive coil structure 41. In addition, in the embodiment, the conductive coil structure 41 is fixedly disposed under the circuit substrate P, and the conductive coil structure 41 and the pin structure 30 are separated by the circuit substrate P and the chip carrying module 2 by a predetermined distance, but the disclosure is not limited thereto. In an embodiment that is not shown, the conductive coil structure 41 may be fixedly disposed above the circuit substrate P. Therefore, in the embodiment, the pin structure 30 is located below the circuit substrate P.

In this way, as shown in FIG. 10, when the electronic chips C are transferred from the chip carrying structure 20 to the circuit substrate P through thrust of the pin structure 30, since the conductive coil structure 41 of the eddy current generating module 4 may approach the corresponding micro heater H, so that the corresponding micro heater H may be heated through the eddy current 4100 generated by the conductive coil structure 41. In addition, when the electronic chips C are transferred from the chip carrying structure 20 to the circuit substrate P through the thrust of the pin structure 30, the two soldering materials B arranged between the electronic chips C and the circuit substrate P may be heated and cured by the corresponding micro heater H. Furthermore, as shown in FIG. 10, in the seventh embodiment (the plurality of micro heaters H are arranged in the circuit substrate P), when the conductive coil structure 41 is approached to the corresponding micro heater H, the heat generated by the corresponding micro heater H may be transferred to the corresponding two soldering materials B through the circuit substrate P to heat the corresponding two soldering materials B. It should be noted that in the embodiment, the mechanism of indirect heating is similar to that of the first embodiment, which is not repeated.

### Eighth Embodiment

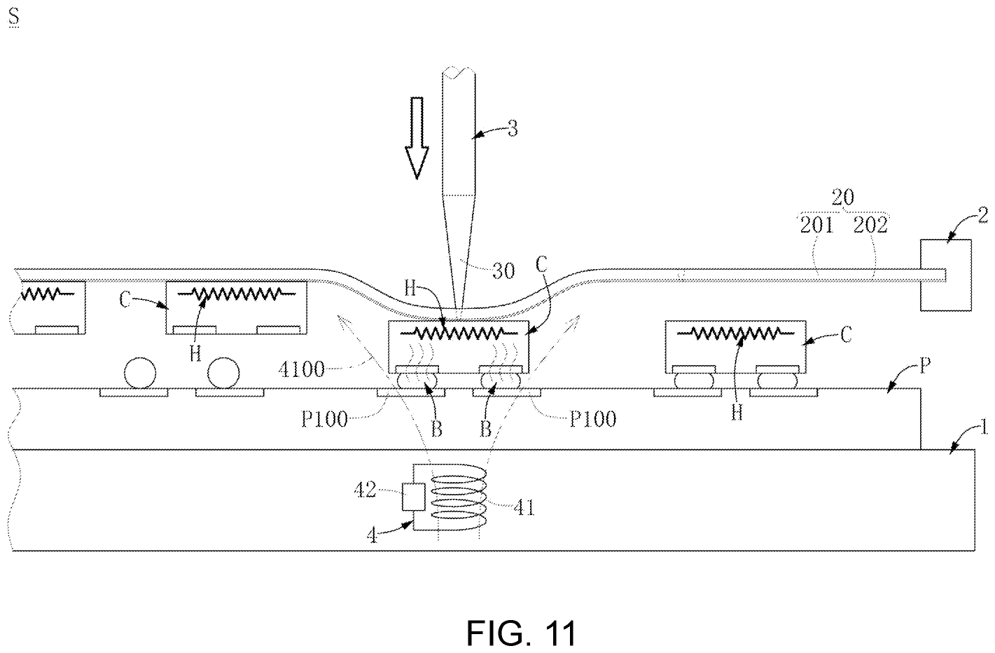

Referring to FIG. 11, the eighth embodiment of the disclosure provides a chip-transferring system S, which includes: a substrate carrying module 1, a chip carrying module 2, a chip thrust module 3, and an eddy current generating module 4. From the comparison between FIG. 11 and FIG. 10, it is learned that the biggest difference between the eighth embodiment and the seventh embodiment of the disclosure is that: in the eighth embodiment, the plurality of micro heaters H are respectively disposed in the plurality of electronic chips C, and the functions of the plurality of micro heaters H are the same as that in the second embodiment. It should be noted that in the embodiment, the mechanism of indirect heating is similar to that of the first embodiment, which is not repeated.

### Ninth Embodiment

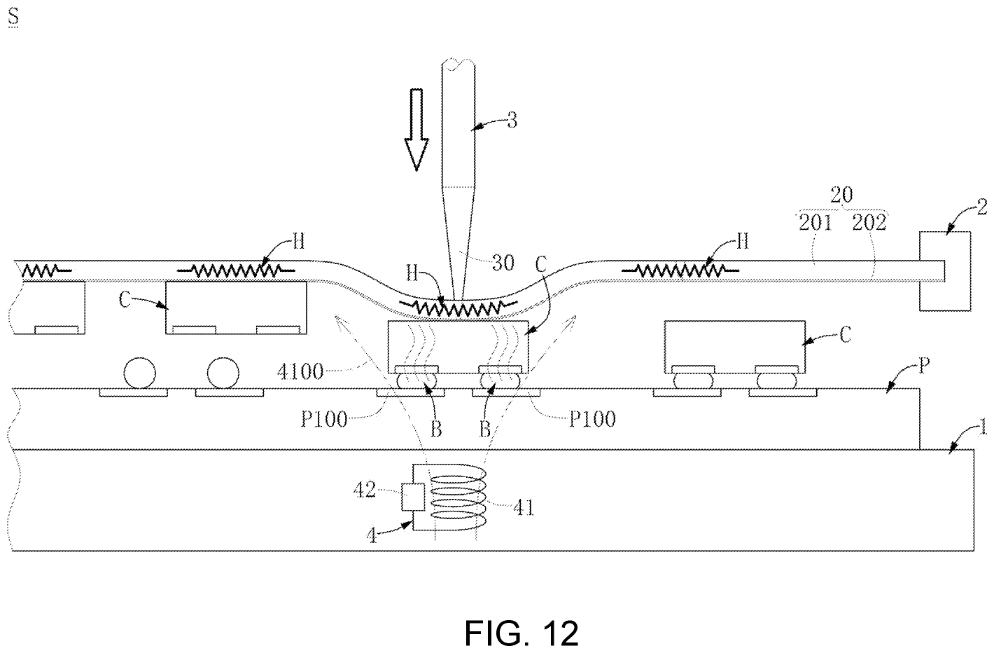

Referring to FIG. 12, the ninth embodiment of the disclosure provides a chip-transferring system S, which includes: a substrate carrying module 1, a chip carrying module 2, a chip thrust module 3, and an eddy current generating module 4. From the comparison between FIG. 12 and FIG. 10, it is learned that the biggest difference between the ninth embodiment and the seventh embodiment of the disclosure is that: in the ninth embodiment, the plurality of micro heaters H are disposed in the chip carrying structure 20, and the functions of the plurality of micro heaters H are the same as that in the third embodiment. It should be noted that in the embodiment, the mechanism of indirect heating is similar to that of the first embodiment, which is not repeated.

### Tenth Embodiment

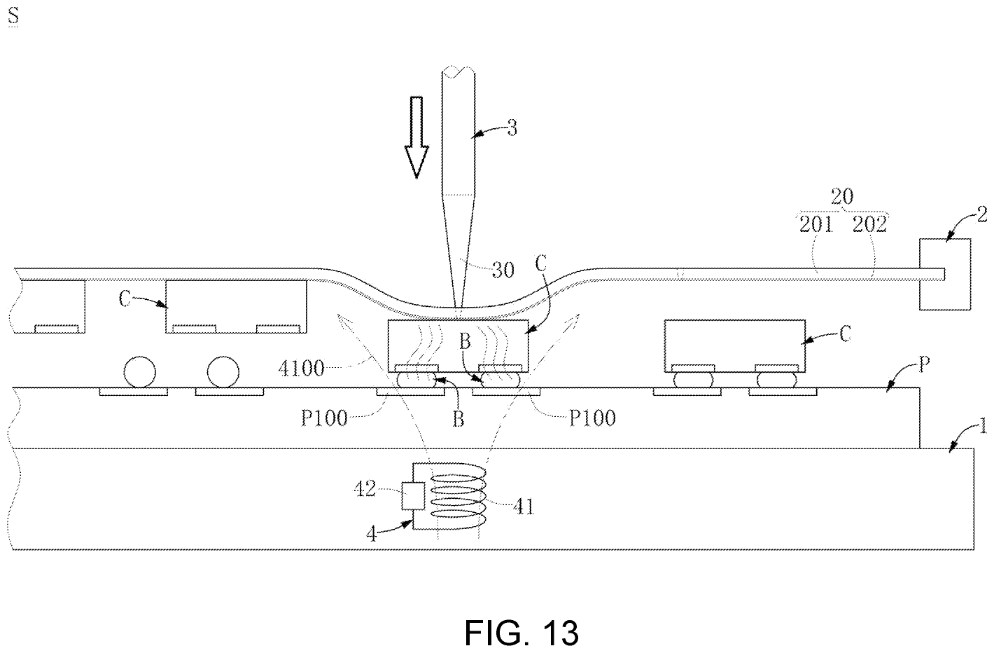

Referring to FIG. 13, the tenth embodiment of the disclosure provides a chip-transferring system S, which includes: a substrate carrying module 1, a chip carrying module 2, a chip thrust module 3, and an eddy current generating module 4. From the comparison between FIG. 13 and FIG. 10, it is learned that the biggest difference between the tenth embodiment and the seventh embodiment of the disclosure is that: in the tenth embodiment, it is unnecessary to use the micro heaters H, and the function of the pin structure 30 of the tenth embodiment is the same as that in the fourth embodiment. It should be noted that in the embodiment, the mechanism of indirect heating is similar to that of the fourth embodiment, which is not repeated.

### Eleventh Embodiment

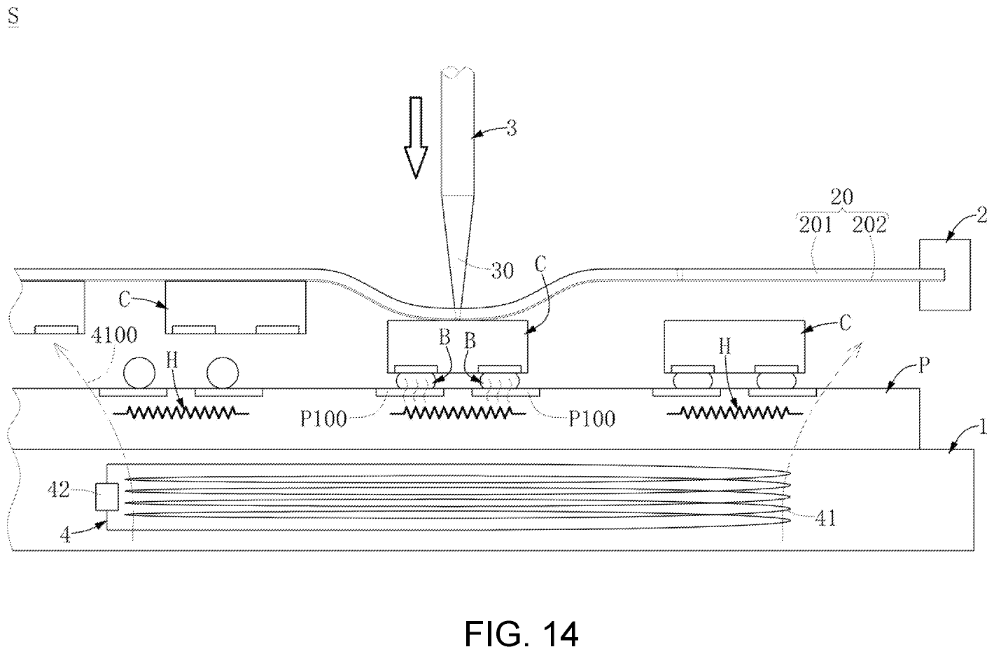

Referring to FIG. 14, the eleventh embodiment of the disclosure provides a chip-transferring system S, which includes: a substrate carrying module 1, a chip carrying module 2, a chip thrust module 3, and an eddy current generating module 4. From the comparison between FIG. 14 and FIG. 10, it is learned that the biggest difference between the eleventh embodiment and the seventh embodiment of the disclosure is that: in the eleventh embodiment, the conductive coil structure 41 is arranged at a position corresponding to one or more micro heaters H, so as to increase the eddy current 4100 provided by the conductive coil structure 41. It should be noted that in the embodiment, the mechanism of indirect heating is similar to that of the first embodiment, which is not repeated.

### Twelfth Embodiment

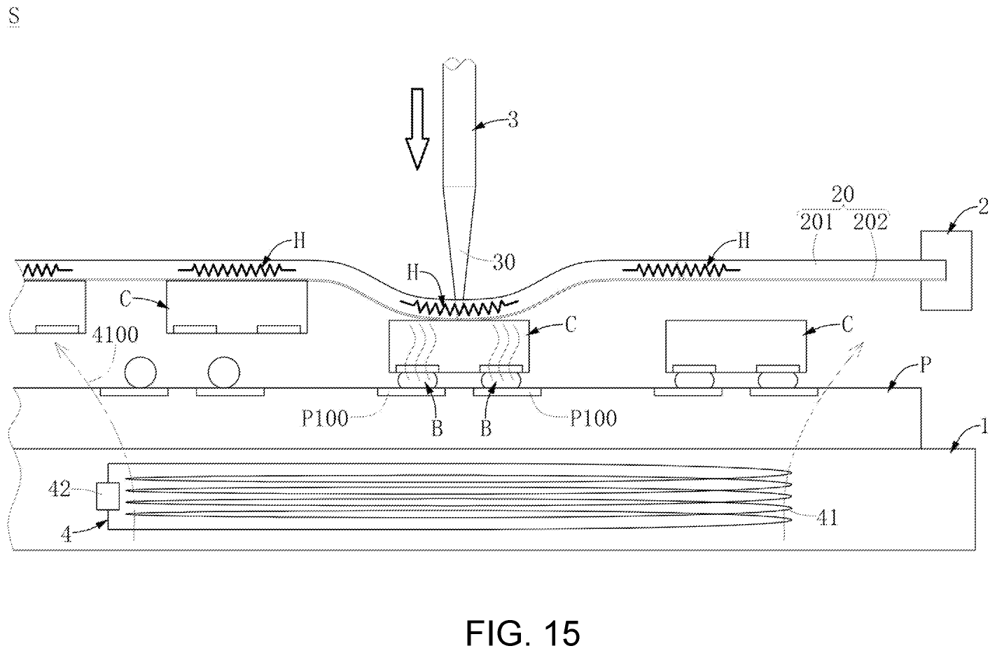

Referring to FIG. 15, the twelfth embodiment of the disclosure provides a chip-transferring system S, which includes: a substrate carrying module 1, a chip carrying module 2, a chip thrust module 3, and an eddy current generating module 4. From the comparison between FIG. 15 and FIG. 12, it is learned that the biggest difference between the twelfth embodiment and the ninth embodiment of the disclosure is that: in the twelfth embodiment, the conductive coil structure 41 is arranged at a position corresponding to one or more micro heaters H, so as to increase the eddy current 4100 provided by the conductive coil structure 41. It should be noted that in the embodiment, the mechanism of indirect heating is similar to that of the first embodiment, which is not repeated.

### Thirteenth Embodiment

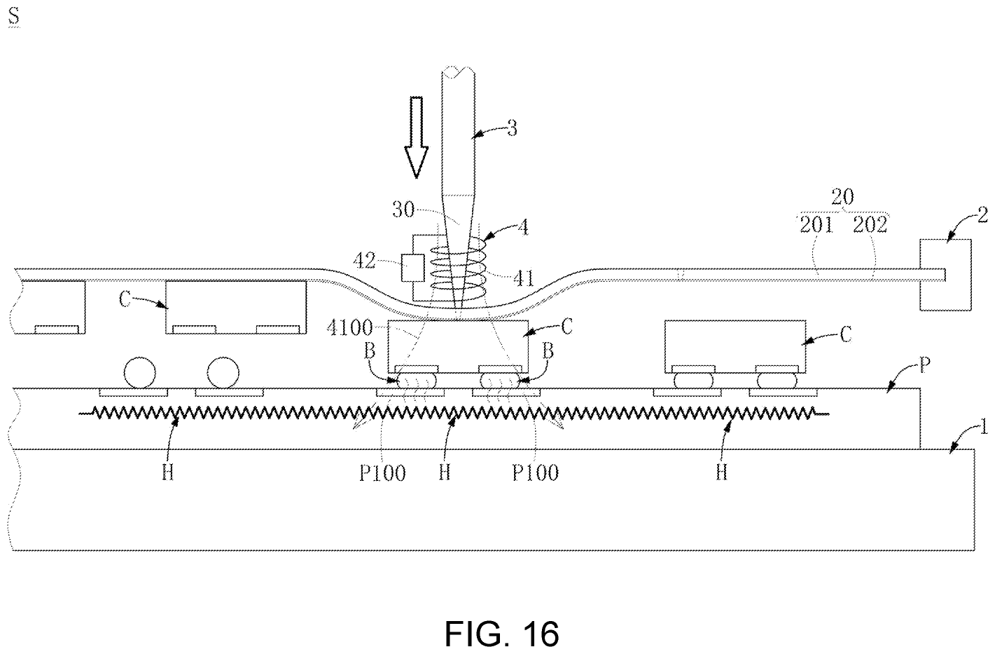

Referring to FIG. 16, the thirteenth embodiment of the disclosure provides a chip-transferring system S, which includes: a substrate carrying module 1, a chip carrying module 2, a chip thrust module 3, and an eddy current generating module 4. From the comparison between FIG. 16 and FIG. 2, it is learned that the biggest difference between the thirteenth embodiment and the first embodiment of the disclosure is that: in the thirteenth embodiment, in order to meet a situation when a size of the electronic chip C is smaller, the size of the electronic chip C is, for example, between 50 μm and 500 μm, the micro heaters H in the circuit substrate P are arranged at positions corresponding to one or more electronic chips C. It should be noted that in the embodiment, the mechanism of indirect heating is similar to that of the first embodiment, which is not repeated. In addition, in an embodiment that is not shown, similar to FIG. 5 and FIG. 16, the micro heaters H in the chip carrying module 2 are arranged at positions corresponding to one or more electronic chips C.

[Beneficial Effects of the Embodiments]

One of the beneficial effects of the disclosure is that the chip-transferring system provided by the disclosure may adopt technical solutions of “the chip thrust module 3 includes the pin structure 30 adjacent to the chip carrying structure 20” and “the eddy current generating module 4 includes the conductive coil structure 41” and “the soldering materials B between the electronic chips C and the circuit substrate P is indirectly heated and cured through the eddy current 4100 generated by the conductive coil structure 41”, the corresponding micro heater or the pin structure may be heated by the eddy current 4100 generated by the conductive coil structure 41, and the two soldering materials B arranged between the electronic chips C and the circuit substrate P may be cured through heating of the corresponding micro heater H or the pin structure 30.

One of the beneficial effects of the disclosure is that the chip-transferring method provided by the disclosure may adopt technical solutions of “providing the pin structure 30 to transfer the electronic chips C from the chip carrying structure 20 to the circuit substrate P through thrust of the pin structure 30” and “approaching the conductive coil structure 41 of the eddy current generating module 4 toward the soldering materials B, so that the soldering materials are heated and cured indirectly through the eddy current 4100 generated by the conductive coil structure 41”, the micro heater H or the pin structure 30 may be heated by the eddy current 4100 generated by the conductive coil structure 41, and the two soldering materials B arranged between the electronic chips C and the circuit substrate P may be cured through heating of the micro heater H or the pin structure 30.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A chip-transferring method, comprising:
providing a chip carrying structure, wherein the chip carrying structure carries an electronic chip;
providing a circuit substrate, wherein a soldering material is configured between the electronic chip and the circuit substrate;
providing a pin structure, wherein the electronic chip is transferred from the chip carrying structure to the circuit substrate through thrust of the pin structure;
approaching a conductive coil structure of an eddy current generating module toward the soldering material, such that an indirect heating of the soldering material is passed through an eddy current generated by the conductive coil structure and then cured.

2. The chip-transferring method as claimed in claim 1, wherein the indirect heating comprises:
bringing the conductive coil structure of the eddy current generating module close to the pin structure to heat the pin structure through the eddy current generated by the conductive coil structure, and
heating and curing the soldering material through heat generated by the pin structure.

3. The chip-transferring method as claimed in claim 1, wherein the indirect heating comprises:
bringing the conductive coil structure of the eddy current generating module close to a micro heater to heat the micro heater through the eddy current generated by the conductive coil structure, and
heating and curing the soldering material through heat generated by the micro heater.

4. The chip-transferring method as claimed in claim 3, wherein
the micro heater is arranged in the circuit substrate, and when the conductive coil structure is approached to the corresponding micro heater, the heat generated by the corresponding micro heater is transferred to the corresponding soldering material through the circuit substrate to heat the corresponding soldering material; or
the micro heater is arranged in the electronic chip, and when the conductive coil structure is approached to the corresponding micro heater, the heat generated by the corresponding micro heater is transferred to the corresponding soldering material through the corresponding electronic chip to heat the corresponding soldering material; or
the micro heater is arranged in the chip carrying structure, and when the conductive coil structure is approached to the corresponding micro heater, the heat generated by the corresponding micro heater is transferred to the corresponding soldering material sequentially through the chip carrying structure and the corresponding electronic chip to heat the corresponding soldering material.

5. The chip-transferring method as claimed in claim 3, wherein the micro heater is a plurality of micro heaters, the plurality of micro heaters are conductive substances, and the plurality of micro heaters are electrically insulated from each other.

6. The chip-transferring method as claimed in claim 3, wherein the pin structure is surrounded by the conductive coil structure, and the conductive coil structure is arranged at a position corresponding to one of the micro heaters or one or more of the micro heaters.

7. The chip-transferring method as claimed in claim 3, wherein the circuit substrate is disposed between the pin structure and the conductive coil structure, and the conductive coil structure is arranged at a position corresponding to one of the micro heaters or one or more of the micro heaters.

8. The chip-transferring method as claimed in claim 3, wherein a size of the electronic chip is between 50 μm and 500 μm.

9. The chip-transferring method as claimed in claim 8, wherein the micro heater is arranged at a position corresponding to one or more of the plurality of electronic chips.

10. A chip-transferring system, comprising:
a pin structure;
a chip carrying structure, carrying a chip group comprising a plurality of electronic chips;
a substrate carrying module, carrying a circuit substrate, wherein the circuit substrate has a plurality of conductive pads; and
an eddy current generating module, comprising a conductive coil structure and a controller electrically connected to the conductive coil structure,
wherein an indirect heating of a soldering material between the electronic chip and the circuit substrate is passed through an eddy current generated by the conductive coil and then cured.

11. The chip-transferring system as claimed in claim 10, wherein the chip-transferring system does not use a micro heater, and the pin structure is configured to indirectly heat and cure the soldering material.

12. The chip-transferring system as claimed in claim 10, further comprising a micro heater, wherein the micro heater is disposed on at least one of the circuit substrate, the chip group, and the chip carrying structure and is configured to indirectly heat and cure the soldering material.

13. The chip-transferring system as claimed in claim 12, wherein the micro heater is a plurality of micro heaters, the plurality of micro heaters are conductive substances, and the plurality of micro heaters are electrically insulated from each other.

14. The chip-transferring system as claimed in claim 12, wherein the pin structure is surrounded by the conductive coil structure, and the conductive coil structure is arranged at a position corresponding to one of the micro heaters or one or more of the micro heaters.

15. The chip-transferring system as claimed in claim 12, wherein the substrate carrying module is disposed between the pin structure and the conductive coil structure, and the conductive coil structure is arranged at a position corresponding to one of the micro heaters or one or more of the micro heaters.

16. The chip-transferring system as claimed in claim 12, wherein the at least one micro heater is arranged at a position corresponding to one or more of the plurality of electronic chips.
